(19) United States
(12) Patent Application Publication
(10) Pub. No.: US 2024/0120259 A1
(43) Pub. Date: Apr. 11, 2024

(54) SEMICONDUCTOR SUBSTRATE, MANUFACTURING METHOD FOR SEMICONDUCTOR SUBSTRATE, AND ELECTRONIC DEVICE HAVING SEMICONDUCTOR SUBSTRATE

(71) Applicant: SONY GROUP CORPORATION, TOKYO (JP)

(72) Inventor: KOICHI TAKEUCHI, KANAGAWA (JP)

(21) Appl. No.: 18/547,344

(22) PCT Filed: Feb. 22, 2022
(86) PCT No.: PCT/JP2022/007189

§ 371 Date: Aug. 22, 2023

(30) Foreign Application Priority Data
Mar. 2, 2021 (JP) 2021-032939

(51) Int. Cl. H01L 23/48; H01L 21/768

(52) U.S. Cl. CPC H01L 23/481; H01L 21/76898

(57) ABSTRACT

Provided are a semiconductor substrate, a manufacturing method for a semiconductor substrate, and an electronic device including the semiconductor substrate, which are capable of preventing bubble formation of a resist due to expansion of air in an opening portion of a through hole and reducing a defect in plating which is a subsequent process.

A semiconductor substrate according to the present disclosure has been configured such that, in a silicon or an interlayer film, any one is formed among: a through electrode including an upper hole portion formed in a forward tapered shape, a lower hole portion formed in a reverse tapered shape, and a step formed at a boundary between the upper hole portion and the lower hole portion; a through electrode including an upper hole portion formed in a forward tapered shape and formed to have a curved shape in a cross section of an opening portion, a lower hole portion formed in a reverse tapered shape, and a step formed at a boundary between the upper hole portion and the lower hole portion; and a through electrode including an upper hole portion formed in a forward tapered shape, a lower hole portion formed in a reverse tapered shape, and a boundary formed between the upper hole portion and the lower hole portion.

### TECHNICAL FIELD

The present disclosure relates to a semiconductor substrate in which a TSV or an interlayer insulating film inside hole bored in a mounting package of a semiconductor device is formed in a stepped hole structure or the like, a manufacturing method for a semiconductor substrate, and an electronic device including the semiconductor substrate.

### BACKGROUND ART

Conventionally, as a three-dimensional mounting technology accompanying higher functionality and higher integration of a semiconductor device, for example, there is used a silicon through electrode (a through silicon via: TSV, hereinafter referred to as a “TSV”) or an interlayer insulating film inside hole that vertically penetrates, in a thickness direction, an insulating interlayer film formed by a silicon substrate, a resin, or the like.

The TSV or the interlayer insulating film inside hole is a through electrode that is for electrically connecting a bottom of a through hole to a connection target electrode, and is obtained by forming the through hole penetrating a silicon substrate or an insulating interlayer film to reach an IO pad, a bump, or the like of the connection target electrode, forming an insulating film on a peripheral portion and an inner peripheral surface of the through hole, opening the through hole toward the connection target electrode, and forming a barrier metal film, a metal seed layer, and a conductive layer inside.

As described above, the TSV or the interlayer insulating film inside hole is used for electrically connecting various three-dimensionally stacked devices in order to achieve miniaturization and high density of the semiconductor device. When the TSV or the interlayer insulating film inside hole is formed as described above, a wiring pattern is formed by photolithography, on a surface of the silicon substrate or the insulating interlayer film in a peripheral portion of the TSV or the interlayer insulating film inside hole. In a process of forming a resist pattern for forming this wiring pattern, tenting is performed.

Specifically, a surface is wet by spin-coating with a thinner on an upper surface of the silicon substrate or the interlayer film in which a through hole is bored in order to form the TSV or the interlayer insulating film inside hole, and then a resist is applied to the upper surface of the silicon substrate or the interlayer film by spin coating with the resist. In this case, a state is established in which an opening portion of the through hole is covered as if being closed with a lid so as not to allow the resist to enter deep inside the through hole. Establishing the state in which the resist covers the opening portion of the through hole in this way is called tenting.

In a case where the resist is allowed to enter deep inside the through hole, in a case of a negative resist, a developer is not sufficiently supplied to the bottom of the through hole, and the resist remains. Furthermore, in a case of a positive resist, light does not reach the bottom of the through hole, so that the resist remains after development. If the resist remains in this way, there arises a problem that a conductive layer cannot be formed deep inside the through hole when a conductive layer is formed by copper plating after the wiring pattern is formed by photolithography. For this reason, tenting is performed so as not to allow the resist to enter deep inside the through hole.

After the resist is applied and the opening portion of the through hole is subjected to tenting, baking is then performed to dry the applied resist. However, there is a problem that, when baking is performed, air inside the through hole expands by heating to cause bubble formation (bursting).

Such bubble formation is likely to occur particularly in a case where a film thickness of the tenting is thin. Therefore, Patent Document 1 and Patent Document 2 are disclosed as prior arts for preventing bubble formation of a tenting film formed in the opening portion of the through hole.

In Patent Document 1, internal curability and sensitivity of a photosensitive resin composition can be further improved by using an oxime-based photopolymerization initiator having a carbazole skeleton for a photosensitive resin having a polymer containing an alkoxy group (Si—OR). Consequently, a highly cured film can be formed. There is disclosed a technique for suppressing deformation due to expansion of air due to baking after tenting by using this characteristic.

Patent Document 2 discloses a technique for improving strength by forming a dry film resist in two layers (exposure is performed twice). Specifically, in a laminated film-coated copper-clad laminated plate obtained by laminating an ultraviolet negative-type photosensitive dry film (A1) and a visible-light negative-type photosensitive dry film (B1) containing an ultraviolet absorber that absorbs an ultraviolet photosensitive wavelength range on one surface or both surfaces of a copper-clad laminated substrate having a through hole or the like, irradiation is performed from a surface of the film (B1) with visible light as a first stage so as to obtain a desired pattern. Thereafter, by performing a developing treatment on the film (B1) to remove coating of a non-irradiated portion, and surfaces of a remaining film (B1) and an exposed film (A1) are irradiated with ultraviolet rays as a second stage to cure the exposed film (A1). In a pattern forming method, subsequently, the film (A1) is formed on a surface of the through hole or the like of the copper-clad laminate plate by peeling off the excess film (A1) and film (B1) with a developing treatment solution.

### CITATION LIST

### Patent Document

Patent Document 1: Japanese Patent Application Laid-Open No. 2013-84010
Patent Document 2: Japanese Patent Application Laid-Open No. 2010-181813

### SUMMARY OF THE INVENTION

### Problems to be Solved by the Invention

However, the techniques of the photosensitive resin composition, the photosensitive resin laminate, and the pattern forming method disclosed in Patent Document 1 improve strength by a composition of a resist material. However, there is a problem that fluidity is high after application containing a large amount of solvent, and expansion of air after tenting cannot be sufficiently suppressed only by the configuration of the resin.

The technique of the pattern forming method disclosed in Patent Document 2 improves strength by forming the dry film resist in two layers (exposure is performed twice). However, there is a problem that high resolution cannot be obtained by the dry film. Furthermore, in a case where a liquid resist is applied, baking is required after application on a lower layer, and thus there is no difference in terms of expansion of air inside the TSV subjected to tenting.

The present disclosure has been made in view of the above-described problems, and is to form a stepped blind hole by forming a step on an inner peripheral surface of a through hole. As a result, it is possible to provide a semiconductor substrate, a manufacturing method for a semiconductor substrate, and an electronic device including the semiconductor substrate, which are capable of preventing bubble formation of a resist due to expansion of air when tenting is performed on an opening portion of a through hole and reducing a defect in plating in a subsequent process.

### Solutions to Problems

The present disclosure has been made to solve the above-described problems, and a first aspect thereof is a semiconductor substrate including a through electrode including: an upper hole portion formed in a forward tapered shape; a lower hole portion formed in a reverse tapered shape; and a step formed at a boundary between the upper hole portion and the lower hole portion.

A second aspect thereof is a semiconductor substrate including a through electrode including: an upper hole portion formed in a forward tapered shape and formed to have a curved shape in a cross section of an opening portion; a lower hole portion formed in a reverse tapered shape; and a step formed at a boundary between the upper hole portion and the lower hole portion.

A third aspect of the present invention is a semiconductor substrate including a through electrode including: an upper hole portion formed in a forward tapered shape; a lower hole portion formed in a reverse tapered shape; and a boundary formed between the upper hole portion and the lower hole portion.

Furthermore, in the first to third aspects, the through electrode may be bored in a silicon substrate.

Furthermore, in the first to third aspects, the through electrode may be bored in an interlayer film having an insulating property.

Furthermore, in the first to third aspects, the through electrode may be bored in two or more interlayer films having an insulating property.

Furthermore, in the first to third aspects, the boundary or the step between the upper hole portion and the lower hole portion may be disposed at a position in a depth direction of 20% to 50% from the opening surface with respect to a depth of the through electrode.

Furthermore, in the first to third aspects, the interlayer film having an insulating property may be formed by resin of an organic material or an inorganic material having photosensitivity.

A fourth aspect thereof is a manufacturing method for a semiconductor substrate, the manufacturing method including: a process of forming a substrate on a wiring layer; a process of boring a through hole having a reverse tapered shape in the silicon substrate or the interlayer film having an insulating property; a process of forming an upper part of the through hole in a forward tapered shape; a process of forming an insulating film on an inner peripheral surface of the through hole and an upper surface of the silicon substrate or the interlayer film having an insulating property; a process of causing a bottom of the through hole to communicate with copper wiring of a wiring layer disposed below the silicon substrate or the interlayer film having an insulating property; a process of forming a seed layer on an upper surface of the insulating film; a process of applying a resist in a tenting state on an opening portion of the through hole and an upper surface of the silicon substrate or the interlayer film having an insulating property, and drying the resist; a process of forming a resist pattern on an upper surface of the silicon substrate or the interlayer film having an insulating property; and a process of forming a pattern by copper plating on an upper surface of the silicon substrate or the interlayer film having an insulating property, by using the resist pattern as a mask.

A fifth aspect of the present invention is an electronic device including any one semiconductor substrate among:
a semiconductor substrate including a through electrode including an upper hole portion formed in a forward tapered shape, a lower hole portion formed in a reverse tapered shape, and a step formed at a boundary between the upper hole portion and the lower hole portion;
a semiconductor substrate including a through electrode including an upper hole portion formed in a forward tapered shape and formed to have a curved shape in a cross section of an opening portion, a lower hole portion formed in a reverse tapered shape, and a step formed at a boundary between the upper hole portion and the lower hole portion; and
a semiconductor substrate including a through electrode including an upper hole portion formed in a forward tapered shape, a lower hole portion formed in a reverse tapered shape, and a boundary formed between the upper hole portion and the lower hole portion.

By adopting the aspect described above, when a liquid resist is applied to an opening surface of the through hole, the resist remains at a position of the step of the stepped hole, and tenting can be performed while maintaining a predetermined film thickness.

According to the present disclosure, an object is to provide a semiconductor substrate, a manufacturing method for a semiconductor substrate, and an electronic device having a solid-state imaging device including the semiconductor substrate, in which a resist for tenting of a through hole can be formed to be thicker than conventional ones, and thus bubble formation of the resist due to expansion of air is prevented and a defect in plating which is a subsequent process is reduced.

### BRIEF DESCRIPTION OF DRAWINGS

FIG. 1 is a schematic cross-sectional view of a solid-state imaging device having a semiconductor substrate in which a TSV is bored.

FIG. 2 is an explanatory view of a process of tenting (part 1).

FIG. 3 is an explanatory view of a process of tenting (part 2).

FIG. 4 is an explanatory view of lithography in a process of tenting.

FIG. 5 is an explanatory view of bubble formation in a process of tenting.

FIG. 6 is an explanatory view of pattern collapse in a process of tenting.

FIG. 7 is a cross-sectional view of a basic form of a tenting state in a first embodiment of a semiconductor substrate according to the present disclosure.

FIG. 8 is an explanatory view of a taper angle on an inner peripheral surface of a through hole and ease of falling of a resist.

FIG. 9 is an explanatory view of a dimensional relationship when an insulating film and a seed layer are formed in the through hole.

FIG. 10 is a cross-sectional view of the semiconductor substrate in a tenting state according to the basic form of the first embodiment.

FIG. 11 is a cross-sectional view of a solid-state imaging device having the semiconductor substrate according to the basic form of the first embodiment.

FIG. 12 is a cross-sectional view of a semiconductor substrate in a tenting state according to Modification 1 of the first embodiment.

FIG. 13 is a cross-sectional view of a solid-state imaging device having the semiconductor substrate according to Modification 1 of the first embodiment.

FIG. 14 is a cross-sectional view of a semiconductor substrate in a tenting state according to Modification 2 of the first embodiment.

FIG. 15 is a cross-sectional view of a solid-state imaging device having the semiconductor substrate according to Modification 2 of the first embodiment.

FIG. 16 is a cross-sectional view of a semiconductor substrate in a tenting state according to a basic form of a second embodiment.

FIG. 17 is a cross-sectional view of a semiconductor substrate in a tenting state according to a basic form of a third embodiment.

FIG. 18 is a process explanatory view (part 1) of a manufacturing method for the basic form of the first embodiment of the semiconductor substrate according to the present disclosure.

FIG. 19 is a process explanatory view (part 2) of the manufacturing method for the basic form of the first embodiment of the semiconductor substrate according to the present disclosure.

FIG. 20 is a process explanatory view (part 3) of the manufacturing method for the basic form of the first embodiment of the semiconductor substrate according to the present disclosure.

FIG. 21 is a process explanatory view (part 4) of the manufacturing method for the basic form of the first embodiment of the semiconductor substrate according to the present disclosure.

FIG. 22 is a process explanatory view (part 5) of the manufacturing method for the basic form of the first embodiment of the semiconductor substrate according to the present disclosure.

FIG. 23 is a process explanatory view (part 6) of the manufacturing method for the basic form of the first embodiment of the semiconductor substrate according to the present disclosure.

FIG. 24 is a process explanatory view (part 1) of a manufacturing method of Modification 1 of the first embodiment of the semiconductor substrate according to the present disclosure.

FIG. 25 is a process explanatory view (part 2) of the manufacturing method of Modification 1 of the first embodiment of the semiconductor substrate according to the present disclosure.

FIG. 26 is a process explanatory view of a manufacturing method of Modification 2 of the first embodiment of the semiconductor substrate according to the present disclosure.

FIG. 27 is a process explanatory view (part 1) of a manufacturing method for the basic form of the second embodiment of the semiconductor substrate according to the present disclosure.

FIG. 28 is a process explanatory view (part 2) of the manufacturing method for the basic form of the second embodiment of the semiconductor substrate according to the present disclosure.

FIG. 29 is a cross-sectional view of a semiconductor substrate obtained by a manufacturing method of Modification 1 of the second embodiment of the semiconductor substrate according to the present disclosure.

FIG. 30 is a cross-sectional view of a semiconductor substrate obtained by a manufacturing method of Modification 2 of the second embodiment of the semiconductor substrate according to the present disclosure.

FIG. 31 is a process explanatory view (part 1) of a manufacturing method for the basic form of the third embodiment of the semiconductor substrate according to the present disclosure.

FIG. 32 is a process explanatory view (part 2) of the manufacturing method for the basic form of the third embodiment of the semiconductor substrate according to the present disclosure.

FIG. 33 is a cross-sectional view of a semiconductor substrate obtained by a manufacturing method of Modification 1 of the third embodiment of the semiconductor substrate according to the present disclosure.

FIG. 34 is a cross-sectional view of a semiconductor substrate obtained by a manufacturing method of Modification 2 of the third embodiment of the semiconductor substrate according to the present disclosure.

FIG. 35 is a configuration diagram of an electronic device having a solid-state imaging device including a semiconductor substrate according to the present disclosure.

### MODE FOR CARRYING OUT THE INVENTION

Next, modes for carrying out the technology according to the present disclosure (hereinafter, referred to as “embodiments”) will be described in the following order with reference to the drawings. Note that, in the drawings below, the same or similar parts are denoted by the same or similar reference numerals. However, the drawings are schematic, and dimensional ratios and the like of the individual parts do not necessarily coincide with actual ones. Furthermore, naturally, even between the drawings, there is included a part in which a relation or a ratio of dimensions of those may differ from each other.
1. Process and problem of tenting
2. First embodiment of semiconductor substrate according to present disclosure
3. Second embodiment of semiconductor substrate according to present disclosure
4. Third embodiment of semiconductor substrate according to present disclosure
5. Manufacturing method of first embodiment for semiconductor substrate according to present disclosure
6. Manufacturing method of second embodiment for semiconductor substrate according to present disclosure
7. Manufacturing method of third embodiment for semiconductor substrate according to present disclosure
8. Electronic device having solid-state imaging device including semiconductor substrate according to present disclosure

<1. Process and Problem of Tenting>

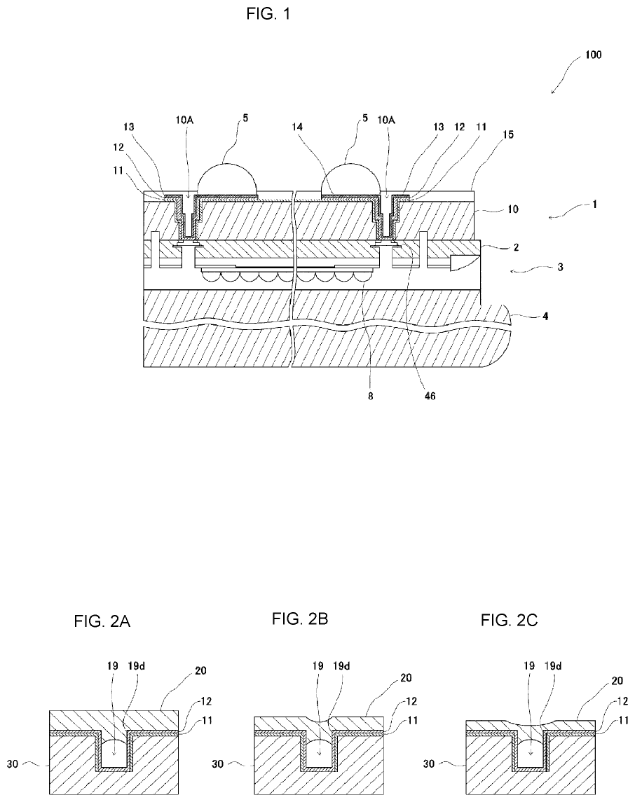

FIG. 1 is a schematic cross-sectional view of a solid-state imaging device 100 having a semiconductor substrate in which a TSV 10A is bored. As illustrated in this figure, a semiconductor substrate 1 of the solid-state imaging device 100 includes a silicon substrate 10, and a sensor substrate 2 having a light receiving unit 3 and disposed on the silicon substrate 10. Then, a cover glass 4 is disposed facing the light receiving unit 3 of the sensor substrate 2. The solid-state imaging device 100 forms an image of incident light from an optical system (not illustrated) on the light receiving unit 3 on the sensor substrate 2 via the cover glass 4 (in this figure, a subject image is incident from a lower side to an upper side).

The light receiving unit 3 is a device that converts an optical signal corresponding to the subject image formed on the light receiving unit 3 into an electrical signal. That is, the incident light from the subject image is received in units of pixels in a pixel region of the light receiving unit 3, and each pixel is photoelectrically converted to generate a signal charge corresponding to the pixel of the subject image, and is transmitted to an outside as a pixel signal.

Therefore, resolution of an image of a subject is determined by the number of pixels, and the resolution of the image increases as the number of pixels increases. The pixel is converted into an electrical signal by a photoelectric conversion element (not illustrated) provided in the sensor substrate 2. The photoelectric conversion element is, for example, a photodiode, and receives light incident as a subject image through the cover glass 4 and photoelectrically converts the light to generate a signal charge. The solid-state imaging device 100 includes a complementary metal oxide semiconductor (CMOS) image sensor chip and a charge coupled device (CCD) image sensor chip.

The semiconductor substrate 1 is provided with an external connection terminal 5 which is for transmitting, to an outside, a pixel signal generated in correspondence to a pixel of a subject image by photoelectric conversion with the sensor substrate 2. Then, in order to connect the sensor substrate 2 and the external connection terminal 5, in a case where the semiconductor substrate 1 has the silicon substrate 10, a through electrode called the TSV 10A is bored. Furthermore, in a case of having an insulating interlayer film 30, an interlayer insulating film inside hole 10B is bored. Therefore, copper wiring 46 disposed on a back surface of the light receiving unit 3 of the sensor substrate 2 is electrically connected to the external connection terminal 5 by a seed layer 12 of the TSV 10A or the interlayer insulating film inside hole 10B, a copper plating layer 13, and a copper wiring pattern 14 extending from the copper plating layer 13.

As illustrated in this figure, the TSV 10A is formed by boring a through hole 19 in the silicon substrate 10 of the semiconductor substrate 1, covering an inner peripheral surface of the through hole 19 with an insulating film 11, and further forming the seed layer 12 and the copper plating layer 13 on an upper surface of the through hole. Then, the copper wiring pattern 14 is extended from the copper plating layer 13 along an upper surface of the semiconductor substrate 1, and the upper surface is further covered with a solder mask 15. As a result, the copper wiring 46 disposed on the back surface of the light receiving unit 3 of the sensor substrate 2 is electrically connected to the external connection terminal 5 via the copper plating layer 13 of the TSV 10A and the wiring pattern 14.

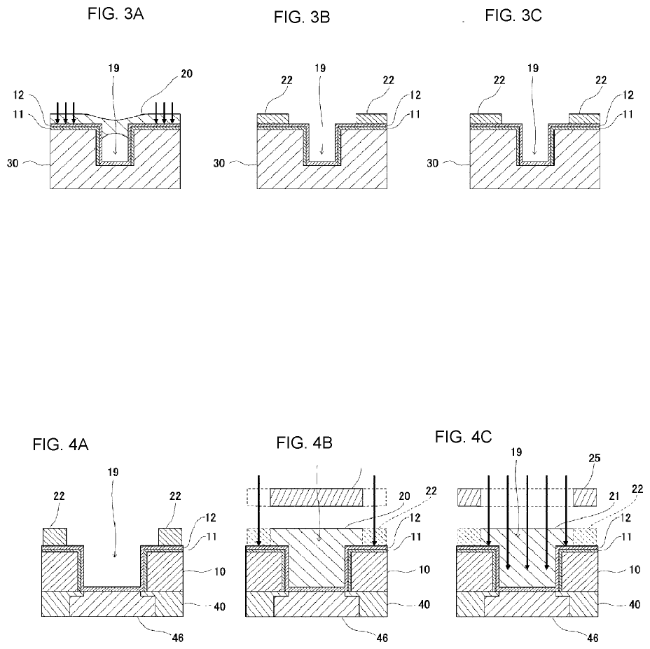

Here, a process of tenting is required to form the TSV 10A. This point will be described in more detail. FIGS. 2 and 3 are views for explaining a process of tenting. In order to form the TSV 10A, as described above, the through hole 19 is bored in the silicon substrate 10, and the inner peripheral surface of the through hole 19 is covered with the insulating film 11. Then, the seed layer 12 is further formed on an upper surface of the insulating film 11 by sputtering or the like. After the seed layer 12 is formed, next, the copper plating layer 13 and the copper wiring pattern 14 are then formed on an upper surface of the seed layer 12 as illustrated in FIG. 1.

In order to form the wiring pattern 14, it is necessary to generate a resist pattern 22 having a shape of the wiring pattern 14 on the upper surface of the semiconductor substrate 1. Therefore, as illustrated in FIG. 2A, a liquid negative resist 20 is dropped on the upper surface of the silicon substrate 10 on which the seed layer 12 is formed, and the liquid negative resist 20 applied as if putting a lid on an opening portion 19d of the through hole 19 uniformly by spin coating. At this time, air is confined in the through hole 19. This state is called “tenting”.

A reason for performing tenting is as follows. That is, as illustrated in FIG. 4A, the through hole 19 is bored in the silicon substrate 10, and the insulating film 11 and the seed layer 12 are formed. Next, a case will be described in which the through hole 19 is filled with a resist without tenting, when the resist pattern 22 as illustrated in FIG. 4A is formed.

In a case where the negative resist 20 is present at a bottom of the through hole 19, as illustrated in FIG. 4B, a development residue is generated because a developer is not sufficiently supplied. Furthermore, in a case where a positive resist 21 is used, as illustrated in FIG. 4C, exposure light through a photomask 25 does not reach the bottom of the through hole 19, and a development residue is similarly generated. When such a development residue is generated, the copper plating layer 13 cannot be sufficiently formed in a subsequent process, and a defect in plating occurs. Furthermore, in a case where a dry resist (film resist) is used, although a tenting state can be formed, there is a problem that a fine pattern cannot be formed as compared with a liquid resist. Therefore, “tenting” is performed so as not to allow the negative resist 20 or the positive resist 21 to enter the through hole 19.

Hereinafter, an example using the negative resist 20 will be described (hereinafter, the “negative resist 20” is referred to as a “resist 20”). After the liquid resist 20 is spin-coated, as illustrated in FIG. 2B, the semiconductor substrate 1 is rotated at a high speed to dry a solvent remaining in the resist 20. Next, as illustrated in FIG. 2C, the semiconductor substrate 1 is subjected to baking (referred to as post applled bake (PAB)) to further dry the solvent. Next, as illustrated in FIG. 3D, exposure is performed through the photomask 25, and as illustrated in FIG. 3E, the resist pattern 22 for forming the wiring pattern 14 extending around the through hole 19 is formed by development. Next, as illustrated in FIG. 3F, baking is performed, and then cooling is performed.

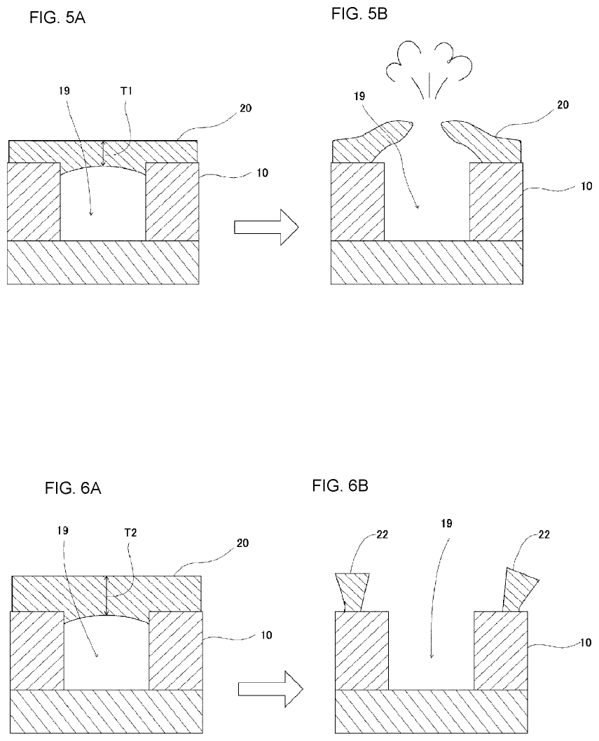

However, as illustrated in FIG. 5A, when baking is performed at a high temperature in order to sufficiently dry the solvent after the liquid resist 20 is applied in a tenting shape, there is a problem that air in the through hole 19 expands to cause bubble formation (bursting) as illustrated in FIG. 5B. Furthermore, in a case where an application film thickness (a thickness T1) of the resist 20 is reduced in order to miniaturize the resist pattern 22, bubble formation is more likely to occur.

Therefore, as illustrated in FIG. 6A, a method of increasing an application film thickness of the resist 20 in order to suppress bubble formation is considered (a thickness T2). However, since a residual solvent of the resist 20 increases and an aspect ratio of the pattern increases, as illustrated in FIG. 6B, there arises a new problem that the resist pattern 22 collapses after exposure and development.

<2. First Embodiment of Semiconductor Substrate According to Present Disclosure>

### [Basic Form of First Embodiment]

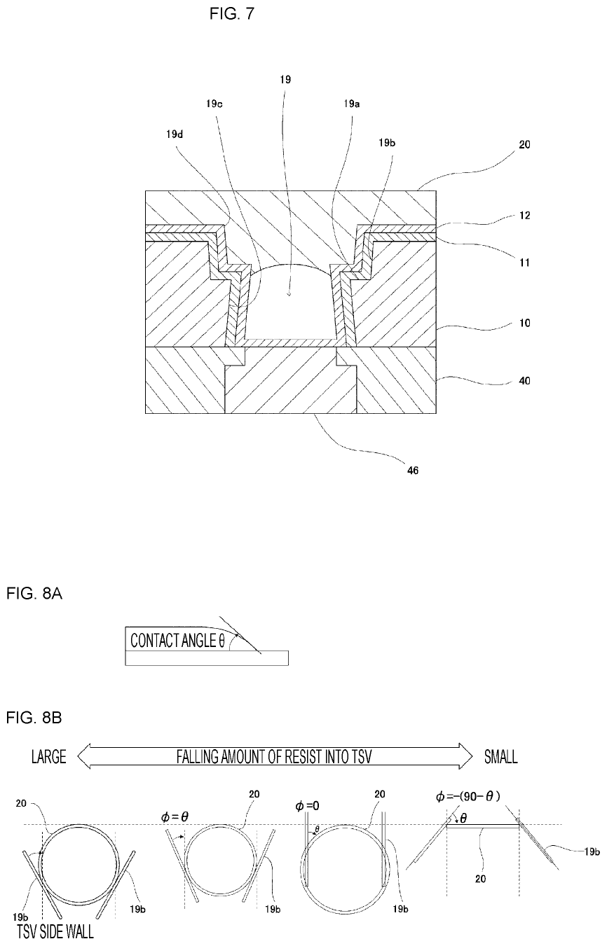

In view of such a problem, as illustrated in FIG. 7, a basic form of the first embodiment according to the present disclosure is obtained by forming a step 19a in a stepwise manner on the inner peripheral surface of the through hole 19, forming an upper hole portion 19b above the step 19a in a forward tapered shape, and forming a lower hole portion 19c below the step 19a in a reverse tapered shape. The step 19a is a step portion forming a horizontal step surface parallel to a plate surface of the silicon substrate 10 in the through hole 19 of the silicon substrate 10. That is, the lower hole portion 19c is a hole portion having a reduced diameter with respect to the upper hole portion 19b. Between an inner peripheral surface of the lower hole portion 19c and an inner peripheral surface of the upper hole portion 19b, an annular horizontal plane is formed along a hole shape of the through hole 19, as a step surface by the step 19a. Note that the “forward tapered shape” is a shape in which an inner diameter of the through hole 19 is gradually reduced in a direction from the opening portion 19d side to the step 19a side in a plate thickness direction of the silicon substrate 10, and the “reverse tapered shape” is a shape in which the inner diameter of the through hole 19 is gradually decreased in a direction opposite to the forward tapered shape.

With such a formation, when the liquid resist 20 is applied, the resist 20 can be held at the step 19a of the upper hole portion 19b. Therefore, it is possible to perform tenting in the upper hole portion 19b. Furthermore, a thickness of the resist 20 on the opening portion 19d of the through hole 19 can be made thicker than before, and bubble formation of the resist 20 due to expansion of air inside the through hole 19 can be prevented. Furthermore, by providing the step 19a, it is possible to suppress the resist 20 from falling into the bottom of the through hole 19, and it is possible to reduce a defect in copper plating which is a subsequent process.

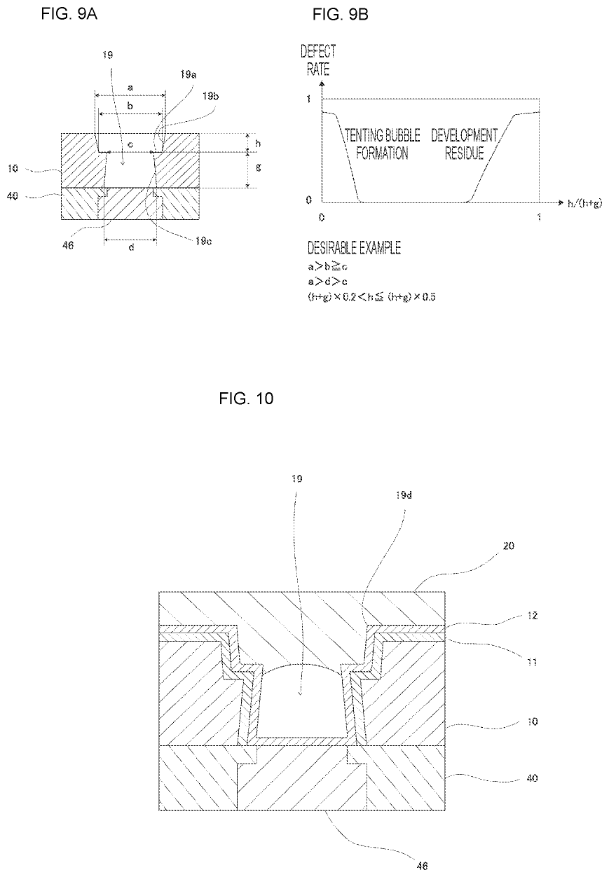

Here, a taper angle Φ on the inner peripheral surface of the through hole 19 and ease of falling of the resist 20 will be described with reference to FIG. 8. A contact angle θ between the liquid resist 20 and the inner peripheral surface is determined by a material of the resist 20 and a type of a material for boring the through hole 19. The resist 20 is subjected to a force to form a spherical shape due to surface tension thereof, and this force acts as a force to suppress entry of the resist 20. Therefore, an interface between air in the through hole 19 and the resist 20 is a part of the spherical surface. Whereas, due to an action of gravity of the earth, a force to fall into the through hole 19 acts on the resist 20. Therefore, as illustrated in FIG. 9, as the inner peripheral surface has a forward taper, a falling amount of the resist becomes larger. Furthermore, the falling amount decreases as the inner peripheral surface has a reverse taper. However, when the reverse taper angle Φ is larger than the contact angle θ, the resist 20 does not fall into the through hole 20.

Therefore, by forming the upper hole portion 19b of the through hole 19 in a forward tapered shape, the resist 20 can be easily to fall. Furthermore, after the resist 20 is once received by the step 19a, the resist 20 can be prevented from falling below the step 19a, by forming the lower hole portion 19c in a reverse tapered shape.

Next, a dimensional relationship when the insulating film 11 and the seed layer 12 are formed in the through hole 19 will be described. In a cross-sectional view of the through hole 19 in FIG. 9A, an opening diameter of the through hole 19 is denoted by a, a diameter of a joint between a lower end of the upper hole portion 19b and the step 19a is denoted by b, a diameter of the step 19a is denoted by c, and a diameter of a lower end of the lower hole portion 19c is denoted by d. Furthermore, a depth of the upper hole portion 19b is denoted by h, and a depth of the lower hole portion 19c is denoted by g.

Accordingly, each of the dimensions described above desirably establishes:

a>b≥c or a>b>c, and

(h+g)×0.2<h≤(h+g)×0.5.

As such a basis, FIG. 9B illustrates a relationship between a defect rate due to tenting bubble formation and a development residue and a ratio h/(h+g) of a depth of the upper hole portion 19b. As illustrated in this figure, a horizontal axis represents h/(h+g), and a vertical axis represents a defect rate. Then, when the value of h/(h+g) becomes close to 0, that is, when h decreases, the thickness of the resist 20 decreases, so that the defect rate of bubble formation increases. Furthermore, when the value of h/(h+g) increases, the thickness of the resist 20 becomes too thick, and the defect rate due to the development residue increases.

Therefore, the depth h of the upper hole portion 19b is set in a range in which bubble formation and development residue do not occur. For example, according to this figure, the step 19a is desirably provided in a range of (h+g)×0.2<h≤(h+g)×0.5.

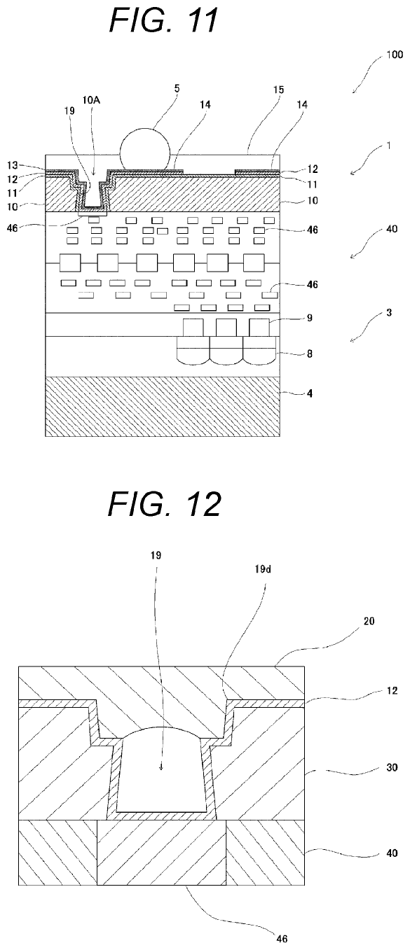

FIG. 10 is a cross-sectional view of the semiconductor substrate 1 in a tenting state according to the basic form of the first embodiment. Furthermore, FIG. 11 is a cross-sectional view of the solid-state imaging device 100 having the semiconductor substrate 1. In the semiconductor substrate 1 of FIGS. 10 and 11, a material for boring the through hole 19 is the silicon substrate 10. Then, on a left side of FIG. 11, the through hole 19 is bored, and the TSV 10A is formed. A periphery of an opening portion of the TSV 10A and an upper surface of the silicon substrate 10 are covered with the insulating film 11 and the seed layer 12, and the copper plating layer 13 is further formed on an upper surface thereof. Furthermore, the wiring pattern 14 is provided by extending the copper plating layer 13. A bottom portion of the TSV 10A is electrically connected to the copper wiring 46 disposed in a wiring layer 40, by the copper plating layer 13.

Note that, in FIG. 11, the copper wiring 46 is formed over several layers in the wiring layer 40 disposed below the silicon substrate 10. The light receiving unit 3 is disposed below the wiring layer 40. A photoelectric conversion element 9 is formed in the light receiving unit 3. The photoelectric conversion element 9 is, for example, a light emitting diode, and is arranged in a matrix for every pixel. For each photoelectric conversion element 9, a microlens array 8 is disposed in correspondence to each photoelectric conversion element 9. Furthermore, the cover glass 4 is disposed facing the photoelectric conversion element 9. The cover glass 4 receives a subject image incident through a lens (not illustrated) or the like of an optical system (in this figure, the subject image is incident from a lower side to an upper side). The photoelectric conversion element 9 converts light incident on the cover glass 4 and the microlens array 8 into an electrical signal in units of pixels. Therefore, resolution of an image of a subject is determined by the number of pixels, that is, the number of photoelectric conversion elements 9, and the resolution of the image increases as the number of pixels increases.

### [Modification 1 of First Embodiment]

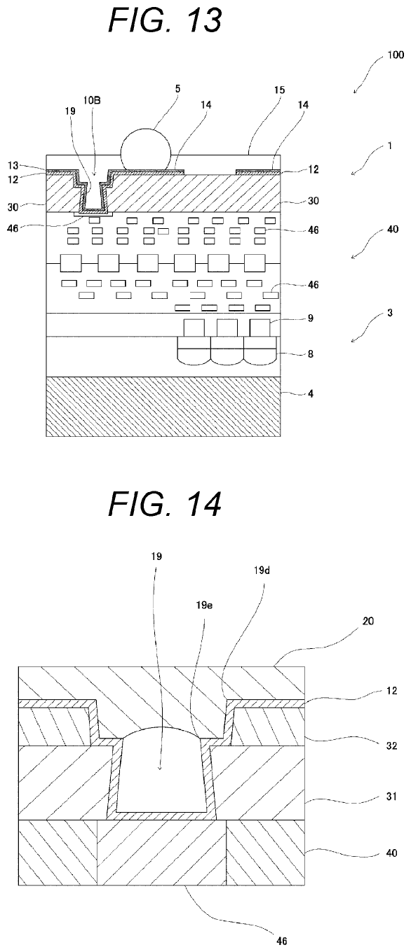

In the basic form of the first embodiment according to the present disclosure, as described above, a material for boring the through electrode 19 of the semiconductor substrate 1 is the silicon substrate 10. Whereas, in Modification 1 of the first embodiment, as illustrated in FIGS. 12 and 13, a material for boring the through electrode 19 of the semiconductor substrate 1 is the interlayer film 30 made with an insulator such as resin.

Specifically, as illustrated in FIG. 12, the through hole 19 is bored in the interlayer film 30, which is an insulator disposed above the wiring layer 40. The inner peripheral surface of the through hole 19 is covered with the seed layer 12, and the seed layer 12 is electrically connected to the copper wiring 46 formed in the wiring layer 40. Then, the resist 20 closes the opening portion 19d of the through hole 19 by tenting. In this Modification 1, since the interlayer film 30 is constituted by an insulator, it is not necessary to provide the insulating film 11 as shown in the basic form in the first place.

Furthermore, the insulating interlayer film 30 may be formed by a resin of an organic material or an inorganic material having photosensitivity. When the interlayer film 30 is formed by such a material, the through hole 19 can be easily bored by exposure through the photomask 25.

Configurations other than those described above are similar to those of the basic form of the first embodiment, and thus description thereof is omitted.

### [Modification 2 of First Embodiment]

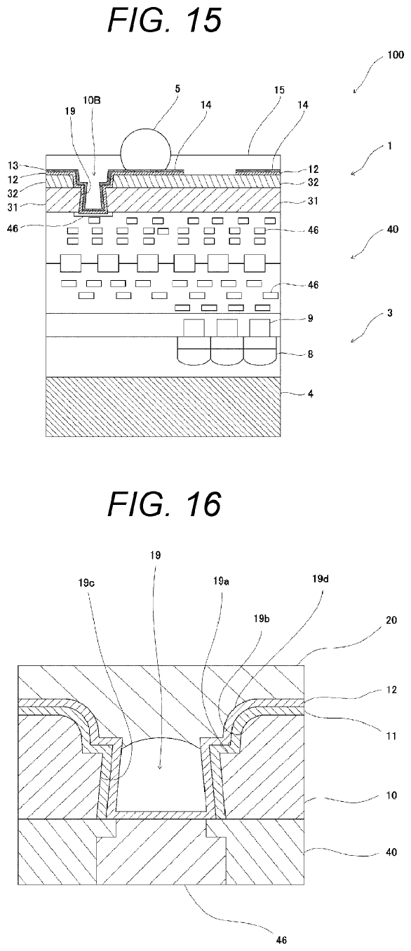

In Modification 2 of the first embodiment according to the present disclosure, as illustrated in FIGS. 14 and 15, a material for boring the through electrode 19 of the semiconductor substrate 1 is a first interlayer film 31 and a second interlayer film 32 made with an insulator such as resin.

Specifically, as illustrated in FIG. 14, the through hole 19 is bored in the first interlayer film 31 and the second interlayer film 32 made with an insulator disposed above the wiring layer 40. More specifically, the lower hole portion 19c of the through hole 19 is bored in the first interlayer film 31, and the upper hole portion 19b of the through hole 19 is bored in the second interlayer film 32. Then, the step 19a is disposed at a boundary 19e between the first interlayer film 31 and the second interlayer film 32. This boundary 19e is also a line where the forward taper of the upper hole portion 19b and the reverse taper of the lower hole portion 19c intersect with each other.

Furthermore, the inner peripheral surface of the through hole 19 is covered with the seed layer 12, and the seed layer 12 is electrically connected to the copper wiring 46 disposed in the wiring layer 40. Then, the resist 20 closes the opening portion 19d of the through hole 19 by tenting. In this Modification 2, the first interlayer film 31 and the second interlayer film 32 are constituted by an insulator. Therefore, the insulating film 11 formed in the basic form does not need to be provided in the first place.

Furthermore, the first interlayer film 31 and the second interlayer film 32, which are insulating, may be formed by a resin of an organic material or an inorganic material having photosensitivity. When the interlayer film 30 is formed by such a material, the through hole 19 can be easily bored by exposure through the photomask 25.

Furthermore, since there is the boundary 19e between the first interlayer film 31 and the second interlayer film 32, it is easy to form the step 19a.

Configurations other than those described above are similar to those of the basic form of the first embodiment, and thus description thereof is omitted.

<3. Second Embodiment of Semiconductor Substrate According to Present Disclosure>

### [Basic Form of Second Embodiment]

A basic form of a second embodiment according to the present disclosure is obtained by, as illustrated in FIG. 16, forming a step 19a in a stepwise manner on an inner peripheral surface of a through hole 19, forming an upper hole portion 19b in a forward tapered shape, forming a lower hole portion 19c in a reverse tapered shape, and forming a cross section of an opening portion 19d of the upper hole portion 19b in a rounded curved shape.

With such a formation, when a liquid resist 20 is applied, the resist 20 easily falls into the through hole 19 since the cross section of the opening portion 19d is formed in a rounded curved shape and the upper hole portion 19b is formed in a forward tapered shape. Moreover, the resist 20 can be held by forming the step 19a. Furthermore, since the lower hole portion 19c is formed in a reverse tapered shape, the resist 20 can be prevented from falling below a boundary 19e. Therefore, it is possible to perform tenting in a state where a thickness of the resist 20 is thicker than that of conventional ones. As a result, it is possible to prevent bubble formation of the resist 20 due to expansion of air. Furthermore, since the step 19a is provided, the resist 20 can be held there, and a defect in copper plating which is a subsequent process can be reduced.

Configurations other than those described above are similar to those of the basic form of the first embodiment, and thus description thereof is omitted.

### [Modification 1 of Second Embodiment]

In Modification 1 of the second embodiment according to the present disclosure, a shape of the through hole 19 is formed similarly to the basic form of the second embodiment illustrated in FIG. 16. Furthermore, a material for boring the through electrode 19 of a semiconductor substrate 1 is constituted by an interlayer film 30 made with an insulator such as a resin, similarly to that described in FIGS. 12 and 13 of Modification 1 of the first embodiment.

Configurations other than those described above are similar to those of the basic form of the second embodiment, and thus description thereof is omitted.

### [Modification 2 of Second Embodiment]

In Modification 2 of the second embodiment according to the present disclosure, a shape of the through hole 19 is similar to that of the basic form of the second embodiment illustrated in FIG. 16. Furthermore, a material for boring the through electrode 19 of the semiconductor substrate 1 is constituted by a first interlayer film 31 and a second interlayer film 32 made with an insulator such as a resin, similarly to FIGS. 14 and 15 described in Modification 2 of the first embodiment.

Configurations other than those described above are similar to those of the basic form of the second embodiment, and thus description thereof is omitted.

<4. Third Embodiment of Semiconductor Substrate According to Present Disclosure>

### [Basic Form of Third Embodiment]

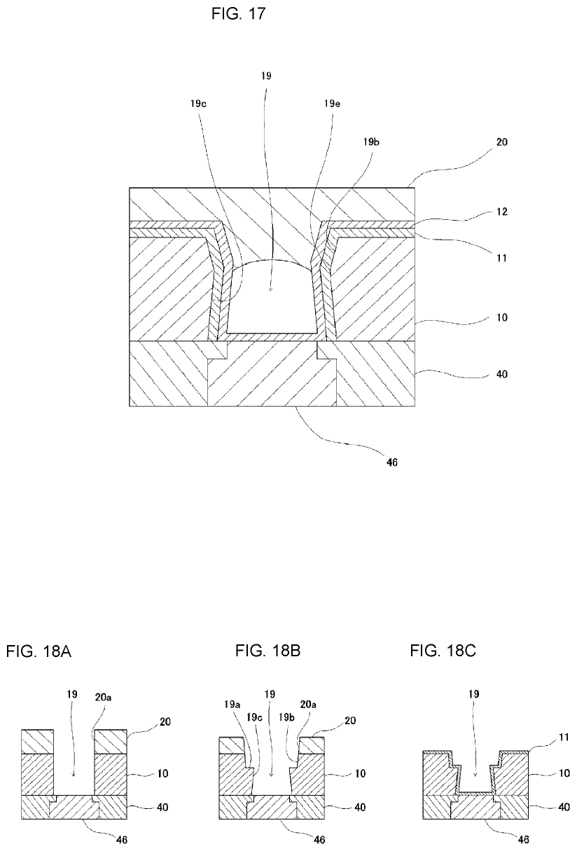

A basic form of a third embodiment according to the present disclosure is obtained by, as illustrated in FIG. 17, eliminating a step 19a of a through hole 19, and forming an upper hole portion 19b in a forward tapered shape and forming a lower hole portion 19c in a reverse tapered shape with respect to a boundary 19e.

With such a formation, when a liquid resist 20 is applied, the resist 20 easily falls into the through hole 19 since the upper hole portion 19b is formed in a forward tapered shape. Furthermore, since the lower hole portion 19c is formed in a reverse tapered shape, the resist is less likely to fall at the boundary 19e where the forward taper is changed to the reverse taper. Therefore, tenting can be performed in a state where a thickness of the resist 20 in the upper hole portion 19b is thicker than that in the other embodiments. As a result, an effect of preventing bubble formation of the resist 20 due to expansion of air can be further improved, and a defect in copper plating which is a subsequent process can be reduced. Furthermore, since the step 19a is not formed, machining becomes easy, leading to reduction of machining time. Note that a slight step 19a may be provided. As a result, a depth at which the resist 20 falls into the bottom of the through hole 19 can be adjusted, so that the thickness of the resist 20 can be adjusted.

Configurations other than those described above are similar to those of the basic form of the first embodiment, and thus description thereof is omitted.

### [Modification 1 of Third Embodiment]

In Modification 1 of the third embodiment according to the present disclosure, a shape of the through hole 19 is similar to that of the basic form of the third embodiment illustrated in FIG. 17. Furthermore, similarly to FIGS. 12 and 13 described in Modification 1 of the first embodiment, a material for boring the through electrode 19 of a semiconductor substrate 1 is constituted by an interlayer film 30 made with an insulator such as resin.

Configurations other than those described above are similar to those of the basic form of the third embodiment, and thus description thereof is omitted.

### [Modification 2 of Third Embodiment]

In Modification 2 of the third embodiment according to the present disclosure, a shape of the through hole 19 is similar to that of the basic form of the third embodiment illustrated in FIG. 17. Furthermore, a material for boring the through electrode 19 of the semiconductor substrate 1 is constituted by a first interlayer film 31 and a second interlayer film 32 made with an insulator such as a resin, similarly to FIGS. 14 and 15 described in Modification 2 of the first embodiment.

Configurations other than those described above are similar to those of the basic form of the third embodiment, and thus description thereof is omitted.

<5. Manufacturing Method of First Embodiment for Semiconductor Substrate According to Present Disclosure>

### [Manufacturing Method for Basic Form of First Embodiment]

Next, a manufacturing method for the basic form of the first embodiment of the semiconductor substrate 1 according to the present disclosure will be described.

First, the silicon substrate 10 is bonded onto the wiring layer 40 having the copper wiring 46, and the silicon substrate 10 is polished and planarized so as to have a desired thickness.

Then, the resist 20 is applied onto a surface of the silicon substrate 10, and a resist pattern of the through hole 19 is formed by a lithography process. At this time, exposure is aligned with a mark formed in a wiring structure. Note that the alignment means a position correction function of performing positioning.

Next, as illustrated in FIG. 18A, by using the resist 20 as a mask, the through hole 19 having a reverse taper is bored on a pad of the copper wiring 46 mainly by anisotropic etching.

Next, as illustrated in FIG. 18B, a resist opening portion 20a is expanded by isotropic ashing, and a cycle process of the anisotropic etching and the isotropic ashing is repeated using the resist 20 as a mask. As a result, the step 19a is formed at the boundary 19e between the lower hole portion 19c and the upper hole portion 19b of the through hole 19, the upper hole portion 19b has a forward tapered shape, and the lower hole portion 19c has a reverse tapered shape.

Next, as illustrated in FIG. 18C, the insulating film 11 (a silicon oxynitride film) containing SiON is formed on an inner peripheral surface of the through hole 19 and an upper surface of the silicon substrate 10 by a chemical vapor deposition (CVD) method. Furthermore, a film is also thinly formed at a bottom of the through hole 19.

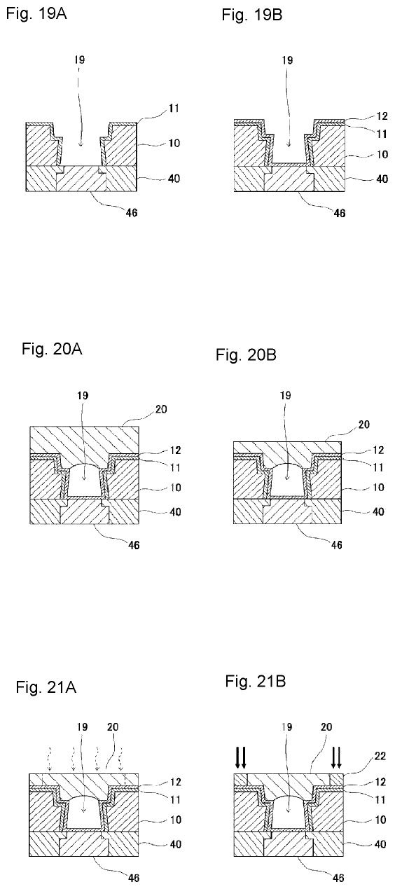

Next, as illustrated in FIG. 19D, the insulating film 11 is etched back by anisotropic etching, and a hole is formed so that the bottom of the through hole 19 communicates with the pad of the copper wiring 46.

Next, as illustrated in FIG. 19E, the seed layer 12 for plating is formed on the inner peripheral surface of the through hole 19 and the upper surface of the silicon substrate 10 by sputtering, in order of a titanium (Ti) layer and a copper (Cu) layer. Thereafter, thinner is dropped on the upper surface of the silicon substrate 10, and a portion above the step 19a is wetted by spin coating while an amount and time of the thinner is being adjusted. That is, the portion above the step 19a is pre-wet with thinner. As a result, when the resist 20 is applied by spin coating in the next process, the resist can fall to the step 19a.

Next, as illustrated in FIG. 20F, the liquid resist 20 is dropped on the silicon substrate 10, and the semiconductor substrate 1 is rotated at a low speed, to apply the resist 20 to the entire upper surface of the silicon substrate 10. At this time, the resist 20 enters the step 19a of the through hole 19, but does not enter the lower hole portion 19c formed in the reverse tapered shape, and air is confined in the lower hole portion 19c of the through hole 19 to establish a tenting state.

Next, as illustrated in FIG. 20G, the semiconductor substrate 1 is rotated at a high speed, to thin the liquid resist 20 and dry a solvent remaining in the liquid resist 20. As a result, the thickness of the resist 20 is slightly reduced and thinned.

Next, as illustrated in FIG. 21H, the semiconductor substrate 1 is heated at about 100° C. to further dry the solvent in the liquid resist 20.

Next, as illustrated in FIG. 21J, a mask is positioned with an alignment mark formed simultaneously with a pattern around the through hole 19, and the copper plating layer 13 and the wiring pattern 14 around the through hole 19 are exposed. The resist 20 in an exposed region is crosslinked.

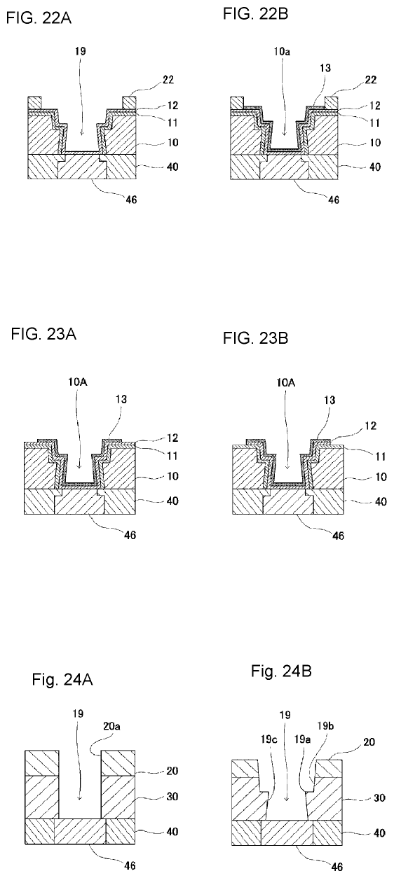

Next, as illustrated in FIG. 22K, the resist 20 that is not crosslinked is removed with a developer. As a result, the resist pattern 22 is formed.

Next, as illustrated in FIG. 22L, copper plating is performed on the inner peripheral surface of the through hole 19 and the upper surface of the silicon substrate 10 by using the resist pattern 22 as a mask. As a result, the copper plating layer 13 is formed.

Next, as illustrated in FIG. 23M, the resist pattern 22 is removed.

Next, as illustrated in FIG. 23N, the seed layer 12 exposed using the copper plating layer 13 as a mask is removed. As a result, the TSV 10A, the copper plating layer 13, and the wiring pattern 14 can be formed on the semiconductor substrate 1.

### [Manufacturing Method of Modification 1 of First Embodiment]

Next, a manufacturing method of Modification 1 of the first embodiment of the semiconductor substrate 1 according to the present disclosure will be described. In this Modification 1, a material for boring the through electrode 19 of the semiconductor substrate 1 is the interlayer film 30 made with an insulator such as resin, instead of the silicon substrate 10.

First, the interlayer film 30 including an organic insulating interlayer film containing an epoxy resin, a polyimide resin, or the like is formed on the wiring layer 40 having the copper wiring 46. The interlayer film 30 is cured by baking at a high temperature or curing by ultraviolet rays (cure: a heating process for stabilizing a structure inside a material).

Then, the resist 20 is applied onto a surface of the interlayer film 30, and the resist pattern 22 of the through hole 19 is formed by a lithography process. At this time, exposure is aligned with a mark formed in a wiring structure.

Next, as illustrated in FIG. 24A, by using the resist 20 as a mask, the through hole 19 having a reverse taper is bored on a pad of the copper wiring 46 mainly by anisotropic etching.

A resist opening portion 20a is expanded by isotropic asking, and a cycle process of the anisotropic etching and the isotropic ashing is repeated using the resist 20 as a mask.

Next, as illustrated in FIG. 24B, a resist opening portion 20a is expanded by isotropic ashing, and a cycle process of the anisotropic etching and the isotropic ashing is repeated using the resist 20 as a mask. As a result, the step 19a is formed at the boundary 19e between the lower hole portion 19c and the upper hole portion 19b of the through hole 19, the upper hole portion 19b has a forward tapered shape, and the lower hole portion 19c has a reverse tapered shape.

Next, as illustrated in FIG. 25C, the resist 20 is removed.

Next, as illustrated in FIG. 25D, the seed layer 12 for plating is formed on the inner peripheral surface of the through hole 19 and the upper surface of the interlayer film 30 by sputtering, in order of a titanium (Ti) layer and a copper (Cu) layer.

The subsequent processes are similar to those in FIGS. 20F to 23N described above. As a result, the interlayer insulating film inside hole 10B, the copper plating layer 13, and the wiring pattern 14 can be formed.

### [Manufacturing Method of Modification 2 of First Embodiment]

Next, a manufacturing method of Modification 2 of the first embodiment of the semiconductor substrate 1 according to the present disclosure will be described. In this Modification 2, a material for boring the through electrode 19 of the semiconductor substrate 1 is the first interlayer film 31 and the second interlayer film 32 made with an insulator such as resin, instead of the silicon substrate 10.

First, the first interlayer film 31 including an organic insulating interlayer film containing an epoxy resin, a polyimide resin, or the like is formed on the wiring layer 40 having the copper wiring 46. The first interlayer film 31 is cured by baking at a high temperature or curing with ultraviolet rays.

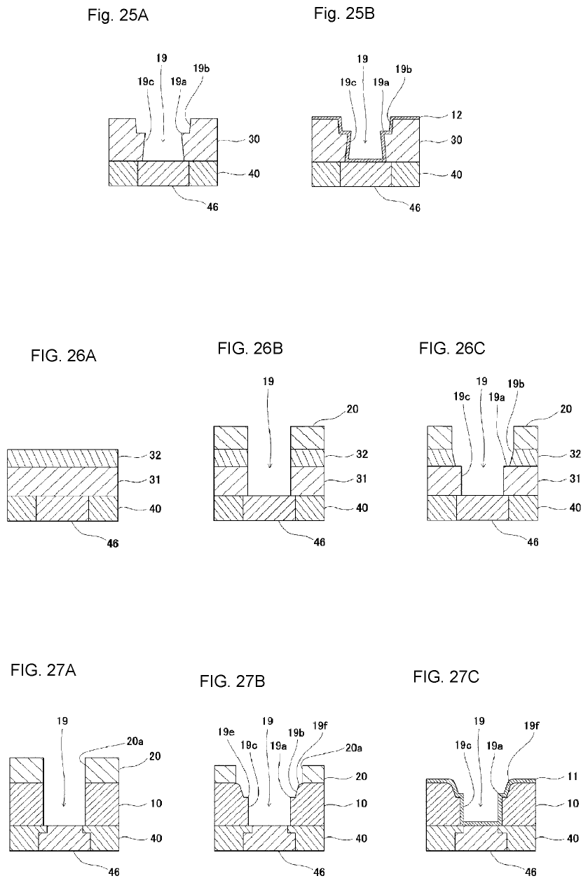

Next, as illustrated in FIG. 26A, the second interlayer film 32 containing a material (for example, Si3N4 (silicon nitride)) different from that of the first interlayer film 31 is formed.

Then, the resist 20 is applied onto a surface of the second interlayer film 32, and the resist pattern 22 of the through hole 19 is formed by a lithography process. At this time, exposure is aligned with a mark formed in a wiring structure.

Next, as illustrated in FIG. 26B, the resist opening portion 20a is expanded by isotropic ashing, and a cycle process of the anisotropic etching and the isotropic ashing is repeated using the resist 20 as a mask. As a result, as illustrated in FIG. 26C, the step 19a is formed at the boundary 19e between the lower hole portion 19c and the upper hole portion 19b of the through hole 19, the upper hole portion 19b has a forward tapered shape, and the lower hole portion 19c has a reverse tapered shape.

Moreover, by setting an etching rate of the second interlayer film 32 higher than that of the first interlayer film 31, as illustrated in FIG. 26C, an upper portion of the lower hole portion 19c is not scraped, and a more stable reverse tapered shape can be formed.

Next, the resist 20 on the second interlayer film 32 is removed.

The subsequent processes are similar to those in FIGS. 20F to 23N described above. As a result, the interlayer insulating film inside hole 10B, the copper plating layer 13, and the wiring pattern 14 can be formed.

<6. Manufacturing Method of Second Embodiment for Semiconductor Substrate According to Present Disclosure>

### [Manufacturing Method for Basic Form of Second Embodiment]

Next, a manufacturing method for the basic form of the second embodiment of the semiconductor substrate 1 according to the present disclosure will be described.

First, the silicon substrate 10 is bonded onto the wiring layer 40 having the copper wiring 46, and the silicon substrate 10 is polished and planarized so as to have a desired thickness.

Then, the resist 20 is applied onto a surface of the silicon substrate 10, and the resist pattern 22 of the through hole 19 is formed by a lithography process. At this time, exposure is aligned with a mark formed in a wiring structure.

Next, as illustrated in FIG. 27A, by using the resist 20 as a mask, the through hole 19 having a reverse taper is bored on a pad of the copper wiring 46 mainly by anisotropic etching.

Next, as illustrated in FIG. 27B, a resist opening portion 20a is expanded by isotropic ashing, and a cycle process of the anisotropic etching and the isotropic ashing is repeated using the resist 20 as a mask. As a result, the step 19a is formed at the boundary 19e between the lower hole portion 19c and the upper hole portion 19b of the through hole 19, the upper hole portion 19b has a forward tapered shape, and the lower hole portion 19c has a reverse tapered shape. Furthermore, a cross section of an opening portion 19f of the upper hole portion 19b has a rounded curved shape.

Next, as illustrated in FIG. 27C, the insulating film 11 containing SiON is formed on an inner peripheral surface of the through hole 19 and an upper surface of the semiconductor substrate 1 by a chemical vapor deposition (CVD) method. Furthermore, a film is also thinly formed at a bottom of the through hole 19. At this time, as illustrated in this figure, conditions of CVD are adjusted such that the insulating film 11 formed in the step 19a overhangs the lower hole portion 19c or the lower hole portion 19c has a reverse tapered shape. However, since the opening portion 19f of the upper hole portion 19b is formed in a forward tapered shape largely, overhang does not occur.

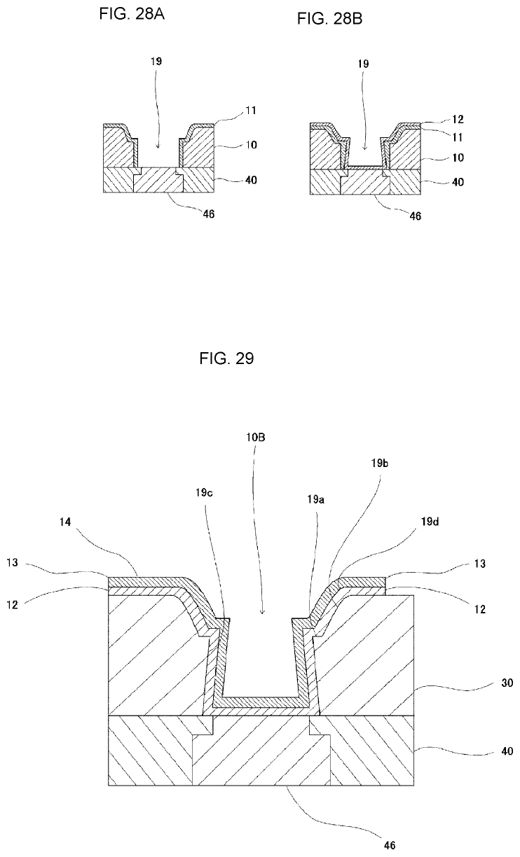

Next, as illustrated in FIG. 28D, the insulating film 11 is etched back by anisotropic etching, and a hole is formed in the bottom of the through hole 19 so that the bottom of the through hole 19 communicates with the pad of the copper wiring 46.

Next, as illustrated in FIG. 28E, the seed layer 12 for plating is formed on the inner peripheral surface of the through hole 19 and the upper surface of the silicon substrate 10 by sputtering, in order of a titanium (Ti) layer and a copper (Cu) layer.

The subsequent processes are similar to those in FIGS. 20F to 23N described above. As a result, the TSV 10A, the copper plating layer 13, and the wiring pattern 14 can be formed.

### [Manufacturing Method of Modification 1 of Second Embodiment]

Next, a manufacturing method of Modification 1 of the second embodiment of the semiconductor substrate 1 according to the present disclosure will be described. In this Modification 1, a material for boring the through electrode 19 of the semiconductor substrate 1 is the interlayer film 30 made with an insulator such as resin, instead of the silicon substrate 10.

Furthermore, similarly to the basic form of the second embodiment, as illustrated in FIG. 16, a shape of the through hole 19 is obtained by forming the step 19a in a stepwise manner on the inner peripheral surface of the through hole 19, forming the upper hole portion 19b in a forward tapered shape, forming the lower hole portion 19c in a reverse tapered shape, and forming a cross section of the opening portion 19d of the upper hole portion 19b in a rounded curved shape.

Although the above is a difference, a manufacturing process is similar to those in FIGS. 24A to 25D described above and FIGS. 20F to 23N described above. As a result, the interlayer insulating film inside hole 10B, the copper plating layer 13, and the wiring pattern 14 as illustrated in FIG. 29 can be formed.

### [Manufacturing Method of Modification 2 of Second Embodiment]

Next, a manufacturing method of Modification 2 of the second embodiment of the semiconductor substrate 1 according to the present disclosure will be described. In this Modification 2, a material for boring the through electrode 19 of the semiconductor substrate 1 is the first interlayer film 31 and the second interlayer film 32 made with an insulator such as resin, instead of the silicon substrate 10.

Furthermore, similarly to the basic form of the second embodiment, as illustrated in FIG. 16, a shape of the through hole 19 is obtained by forming the step 19a in a stepwise manner on the inner peripheral surface of the through hole 19, forming the upper hole portion 19b in a forward tapered shape, forming the lower hole portion 19c in a reverse tapered shape, and forming a cross section of the opening portion 19d of the upper hole portion 19b in a rounded curved shape.

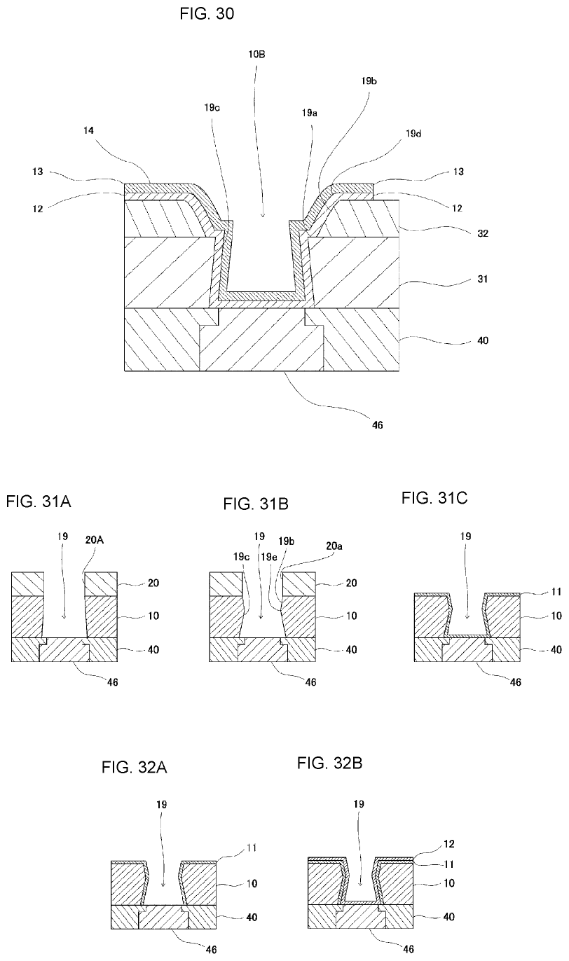

Although the above is a difference, a manufacturing process is similar to those in FIGS. 24A to 25D described above and FIGS. 20F to 23N described above. As a result, the interlayer insulating film inside hole 10B, the copper plating layer 13, and the wiring pattern 14 as illustrated in FIG. 30 can be formed.

<7. Manufacturing Method of Third Embodiment for Semiconductor Substrate According to Present Disclosure>

### [Manufacturing Method for Basic Form of Third Embodiment]

Next, a manufacturing method for the basic form of the third embodiment of the semiconductor substrate 1 according to the present disclosure will be described. First, the silicon substrate 10 is bonded onto the wiring layer 40 having the copper wiring 46, and the silicon substrate 10 is polished and planarized so as to have a desired thickness.

Then, the resist 20 is applied on a surface of the silicon substrate 10, and a resist pattern of the through hole 19 is formed by a lithography process. At this time, exposure is aligned with a mark formed in a wiring structure.

Next, as illustrated in FIG. 31A, by using the resist 20 as a mask, the through hole 19 having a reverse taper is bored on a pad of the copper wiring 46 mainly by anisotropic etching.

Next, as illustrated in FIG. 31B, a resist opening portion 20a is expanded by isotropic ashing, and a cycle process of the anisotropic etching and the isotropic ashing is repeated using the resist 20 as a mask. As a result, the boundary 19e of the through hole 19, the upper hole portion 19b above, and the lower hole portion 19c below are formed, the upper hole portion 19b has a forward tapered shape, and the lower hole portion 19c has a reverse tapered shape.

Next, as illustrated in FIG. 31C, the insulating film 11 containing SiON is formed on an inner peripheral surface of the through hole 19 and an upper surface of the semiconductor substrate 1 by the CVD method. Furthermore, a film is also thinly formed at a bottom of the through hole 19.

Next, as illustrated in FIG. 32D, the insulating film 11 is etched back by anisotropic etching, and a hole is formed in the bottom of the through hole 19 so that the bottom of the through hole 19 communicates with the pad of the copper wiring 46.

Next, as illustrated in FIG. 32E, the seed layer 12 for plating is formed on the inner peripheral surface of the through hole 19 and the upper surface of the silicon substrate 10 by sputtering, in order of a titanium (Ti) layer and a copper (Cu) layer.

The subsequent processes are similar to those in FIGS. 20F to 23N described above. As a result, the TSV 10A, the copper plating layer 13, and the wiring pattern 14 can be formed.

### [Manufacturing Method of Modification 1 of Third Embodiment]

Next, a manufacturing method of Modification 1 of the third embodiment of the semiconductor substrate 1 according to the present disclosure will be described. In this Modification 1, a material for boring the through electrode 19 of the semiconductor substrate 1 is the interlayer film 30 made with an insulator such as resin, instead of the silicon substrate 10.

Furthermore, similarly to the basic form of the third embodiment, as illustrated in FIG. 17, a shape of the through hole 19 is a shape obtained by eliminating the step 19a of the through hole 19, providing the boundary 19e, forming the upper hole portion 19b in a forward tapered shape, and forming the lower hole portion 19c in a reverse tapered shape.

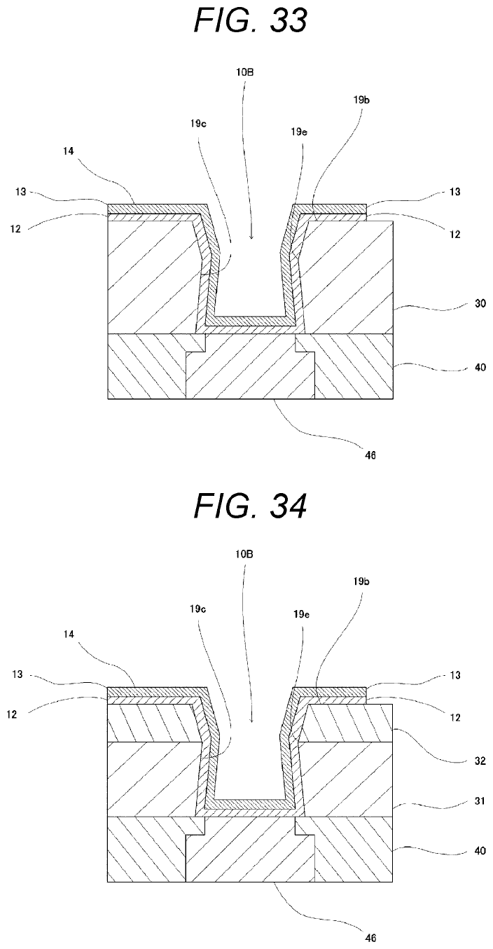

Although there is the difference described above, a manufacturing process is similar to those in FIGS. 24A to 25D described above and FIGS. 20F to 23N described above. As a result, the interlayer insulating film inside hole 10B, the copper plating layer 13, and the wiring pattern 14 as illustrated in FIG. 33 can be formed.

### [Manufacturing Method of Modification 2 of Third Embodiment]

Next, a manufacturing method of Modification 2 of the third embodiment of the semiconductor substrate 1 according to the present disclosure will be described. In this Modification 2, a material for boring the through electrode 19 of the semiconductor substrate 1 is the first interlayer film 31 and the second interlayer film 32 made with an insulator such as resin, instead of the silicon substrate 10.

Furthermore, similarly to the basic form of the third embodiment, as illustrated in FIG. 17, a shape of the through hole 19 is a shape obtained by eliminating the step 19a of the through hole 19, providing the boundary 19e, forming the upper hole portion 19b in a forward tapered shape, and forming the lower hole portion 19c in a reverse tapered shape.

Although the above is a difference, a manufacturing process is similar to those in FIGS. 24A to 25D described above and FIGS. 20F to 23N described above. As a result, the interlayer insulating film inside hole 10B, the copper plating layer 13, and the wiring pattern 14 as illustrated in FIG. 34 can be formed.

Through the processes described above, it is possible to provide the semiconductor substrate 1 and the manufacturing method for the semiconductor substrate 1 that reduce a defect in plating.

<8. Electronic Device Having Solid-State Imaging Device Including Semiconductor Substrate According to Present Disclosure>

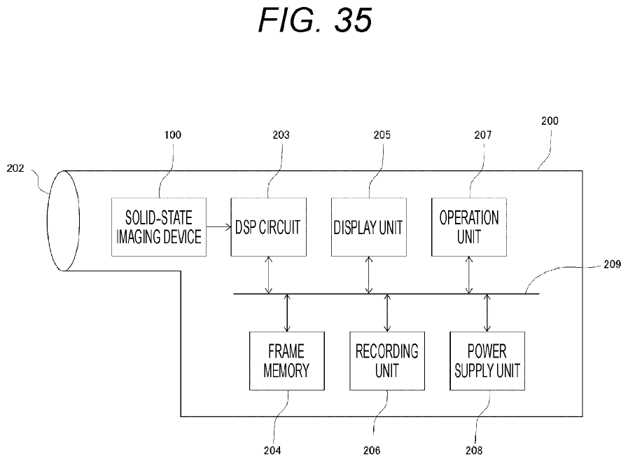

A configuration example of an electronic device having the solid-state imaging device 100 including the semiconductor substrates 1 according to the first to third embodiments described above will be described with reference to FIG. 35.

The solid-state imaging device 100 is applicable to all electronic devices including an image capturing unit (photoelectric conversion unit), such as an imaging device such as a digital still camera or a video camera, a mobile terminal device having an imaging function, and a copying machine using the solid-state imaging device 100 for an image reading unit. The solid-state imaging device 100 may be formed as one chip, or may be in the form of a module having an imaging function in which an imaging unit and a signal processing unit or an optical system are packaged together.

As illustrated in FIG. 35, an imaging device 200 as an electronic device includes an optical unit 202, the solid-state imaging device 100, a digital signal processor (DSP) circuit 203 which is a camera signal processing circuit, a frame memory 204, a display unit 205, a recording unit 206, an operation unit 207, and a power supply unit 208. The DSP circuit 203, the frame memory 204, the display unit 205, the recording unit 206, the operation unit 207, and the power supply unit 208 are connected to one another via a bus line 209.

The optical unit 202 includes a plurality of lenses, and captures incident light (image light) from a subject, to form an image on the light receiving unit 3 of the solid-state imaging device 100. The solid-state imaging device 100 converts an amount of incident light formed as an image on the light receiving unit 3 by the optical unit 202, into an electrical signal in units of pixels in the photoelectric conversion element 9 of the light receiving unit 3, and outputs the electrical signal as a pixel signal.

The display unit 205 including a panel display device such as a liquid crystal panel and an organic electro luminescence (EL) panel, for example, displays a moving image or a still image captured by the solid-state imaging device 100. The recording unit 206 records the moving image or the still image captured by the solid-state imaging device 100 on a recording medium such as a hard disk or a semiconductor memory.

The operation unit 207 issues operation commands for various functions of the imaging device 200 under operation by the user. The power supply unit 208 appropriately supplies various power sources serving as operation power sources of the DSP circuit 203, the frame memory 204, the display unit 205, the recording unit 206, and the operation unit 207 to these supply targets.

As described above, according to the present disclosure, it is possible to reliably perform tenting of the opening portion 19d of the through hole 19, and thus, it is possible to improve the defect rate. As a result, the imaging device 200 having the solid-state imaging device 100 including the semiconductor substrate 1 according to the present disclosure can be provided with high quality.

Finally, the description of each of the above-described embodiments is an example of the present disclosure, and the present disclosure is not limited to the above-described embodiments. For this reason, it is needless to say that various modifications other than the above-described embodiments can be made according to the design and the like without departing from the technical idea according to the present disclosure. Furthermore, the effects described in the present specification are merely examples and are not limited, and other effects may be provided.

Note that the present technology can also have the following configuration.

(1)

A semiconductor substrate including a through electrode including:
an upper hole portion formed in a forward tapered shape;
a lower hole portion formed in a reverse tapered shape; and
a step formed at a boundary between the upper hole portion and the lower hole portion.
   (2)

A semiconductor substrate including a through electrode including:
an upper hole portion formed in a forward tapered shape and formed to have a curved shape in a cross section of an opening portion;
a lower hole portion formed in a reverse tapered shape; and
a step formed at a boundary between the upper hole portion and the lower hole portion.
   (3)

A semiconductor substrate including a through electrode including:
an upper hole portion formed in a forward tapered shape;
a lower hole portion formed in a reverse tapered shape; and
a boundary formed between the upper hole portion and the lower hole portion.
   (4)

The semiconductor substrate according to any one of (1) to (3) above, in which the through electrode is bored in a silicon.

(5)

The semiconductor substrate according to any one of (1) to (3) above, in which the through electrode is bored in an interlayer film having an insulating property.

(6)

The semiconductor substrate according to any one of (1) to (3) above, in which the through electrode is bored in two or more interlayer films having an insulating property.

(7)

The semiconductor substrate according to any one of (1) to (3) above, in which the boundary or the step between the upper hole portion and the lower hole portion is disposed at a position in a depth direction of 20% to 50% from the opening surface with respect to a depth of the through electrode.

(8)

The semiconductor substrate according to (5) or (6) above, in which the interlayer film having an insulating property is formed by a resin of an organic material or an inorganic material having photosensitivity.

(9)

A manufacturing method for a semiconductor substrate, the manufacturing method including:
a process of forming a substrate on a wiring layer;
a process of boring a through hole having a reverse tapered shape in the silicon or the interlayer film having an insulating property;
a process of forming an upper part of the through hole in a forward tapered shape;
a process of forming an insulating film on an inner peripheral surface of the through hole and an upper surface of the silicon substrate or the interlayer film having an insulating property;
a process of causing a bottom of the through hole to communicate with copper wiring of a wiring layer disposed below the silicon or the interlayer film having an insulating property;
a process of forming a seed layer on an upper surface of the insulating film;
a process of applying a resist in a tenting state on an opening portion of the through hole and an upper surface of the silicon or the interlayer film having an insulating property, and drying the resist;
a process of forming a resist pattern on an upper surface of the silicon or the interlayer film having an insulating property; and
a process of forming a pattern by copper plating on an upper surface of the silicon or the interlayer film having an insulating property, by using the resist pattern as a mask.
   (10)

An electronic device including any one semiconductor substrate among:
a semiconductor substrate including a through electrode including
an upper hole portion formed in a forward tapered shape,
a lower hole portion formed in a reverse tapered shape, and
a step formed at a boundary between the upper hole portion and the lower hole portion;
a semiconductor substrate including a through electrode including
an upper hole portion formed in a forward tapered shape and formed to have a curved shape in a cross section of an opening portion,
a lower hole portion formed in a reverse tapered shape, and
a step formed at a boundary between the upper hole portion and the lower hole portion; and
a semiconductor substrate including a through electrode including
an upper hole portion formed in a forward tapered shape,
a lower hole portion formed in a reverse tapered shape, and
a boundary formed between the upper hole portion and the lower hole portion.

### REFERENCE SIGNS LIST

1 Semiconductor substrate
2 Sensor substrate
3 Light receiving unit
4 Cover glass
5 External connection terminal
8 Microlens array
9 Photoelectric conversion element
10 Silicon substrate
10A TSV
10B Interlayer insulating film inside hole
11 Insulating film
12 Seed layer
13 Copper plating layer
14 Wiring pattern
15 Solder mask
19 Through hole
19a Step
19b Upper hole portion
19c Lower hole portion
19d, f Opening portion
19e Boundary
20 Resist
20a Resist opening portion
21 Positive resist
22 Resist pattern
25 Photomask
30 Interlayer film
31 First interlayer film
32 Second interlayer film
40 Wiring layer
46 Copper wiring
100 Solid-state imaging device
200 Imaging device

1. A semiconductor substrate comprising a through electrode including:
an upper hole portion formed in a forward tapered shape;
a lower hole portion formed in a reverse tapered shape; and
a step formed at a boundary between the upper hole portion and the lower hole portion.

2. A semiconductor substrate comprising a through electrode including:
an upper hole portion formed in a forward tapered shape and formed to have a curved shape in a cross section of an opening portion;
a lower hole portion formed in a reverse tapered shape; and
a step formed at a boundary between the upper hole portion and the lower hole portion.

3. A semiconductor substrate comprising a through electrode including:
an upper hole portion formed in a forward tapered shape;
a lower hole portion formed in a reverse tapered shape; and
a boundary formed between the upper hole portion and the lower hole portion.

4. The semiconductor substrate according to claim 1, wherein the through electrode is bored in a silicon.

5. The semiconductor substrate according to claim 1, wherein the through electrode is bored in an interlayer film having an insulating property.

6. The semiconductor substrate according to claim 1, wherein the through electrode is bored in two or more interlayer films having an insulating property.

7. The semiconductor substrate according to claim 1, wherein the boundary or the step between the upper hole portion and the lower hole portion is disposed at a position in a depth direction of 20% to 50% from the opening surface with respect to a depth of the through electrode.

8. The semiconductor substrate according to claim 5, wherein the interlayer film having an insulating property is formed by a resin of an organic material or an inorganic material having photosensitivity.

9. A manufacturing method for a semiconductor substrate, the manufacturing method comprising:
a process of forming a substrate on a wiring layer;
a process of boring a through hole having a reverse tapered shape in the silicon substrate or the interlayer film having an insulating property;
a process of forming an upper part of the through hole in a forward tapered shape;
a process of forming an insulating film on an inner peripheral surface of the through hole and an upper surface of the silicon substrate or the interlayer film having an insulating property;
a process of causing a bottom of the through hole to communicate with copper wiring of a wiring layer disposed below the silicon substrate or the interlayer film having an insulating property;
a process of forming a seed layer on an upper surface of the insulating film;
a process of applying a resist in a tenting state on an opening portion of the through hole and an upper surface of the silicon substrate or the interlayer film having an insulating property, and drying the resist;
a process of forming a resist pattern on an upper surface of the silicon substrate or the interlayer film having an insulating property; and
a process of forming a pattern by copper plating on an upper surface of the silicon substrate or the interlayer film having an insulating property, by using the resist pattern as a mask.

10. An electronic device comprising any one semiconductor substrate among:
a semiconductor substrate including a through electrode including
an upper hole portion formed in a forward tapered shape,
a lower hole portion formed in a reverse tapered shape, and
a step formed at a boundary between the upper hole portion and the lower hole portion;
a semiconductor substrate including a through electrode including
an upper hole portion formed in a forward tapered shape and formed to have a curved shape in a cross section of an opening portion,
a lower hole portion formed in a reverse tapered shape, and
a step formed at a boundary between the upper hole portion and the lower hole portion; and
a semiconductor substrate including a through electrode including
an upper hole portion formed in a forward tapered shape,
a lower hole portion formed in a reverse tapered shape, and
a boundary formed between the upper hole portion and the lower hole portion.
